(19) United States
(12) Patent Application Publication
(10) Pub. No.: US 2003/0184323 A1
(43) Pub. Date: Oct. 2, 2003

(54) Inhibitor funtion check method and apparatus

(76) Inventor: Glyn Christopher Morgan, Leicestershire (GB)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/296,202

(22) PCT Filed: May 30, 2001
(86) PCT No.: PCT/GB01/02380

(30) Foreign Application Priority Data
Jun. 1, 2000 (GB) 0013250.6

(51) Int. Cl. G01R 27/08

(52) U.S. Cl. 324/700

(57) ABSTRACT

The method detects the presence of an effective corrosion inhibitor in a central heating system liquid. A clean steel electrode and a non-steel electrode are immersed in the system liquid. The galvanic current flowing between the electrodes is measured after a delay, and the measured current is compared with a reference. A portable apparatus for carrying out the method comprises a sample container (10) and a measurement instrument (12) which includes a steel electrode (14), a non-steel electrode (16), circuitry (19) for detecting galvanic current flowing between the electrodes when immersed in a test liquid in the container, and generating a measurement signal indicative of the measured galvanic current. The method and apparatus provide a quick effective method of checking correct inhibitor function.

### FIELD OF THE INVENTION

The present invention relates to a method of detecting the presence of an effective corrosion inhibitor in a central heating system liquid and to a portable apparatus for carrying out the method.

### BACKGROUND OF THE INVENTION

Central heating systems are recommended to contain a corrosion inhibitor, usually comprising a proprietary blend of organic and inorganic chemicals, such as Sentinel X100 (ex BetzDearborne Ltd., UK) or Fernox Superconcentrate (ex Fry Technology, UK), (typically but not exclusively made up of mixtures of the following classes of chemicals: amines, benzoates, benzotriazoles, molybdates, nitrites, phosphates and silicates) to protect the metal parts such as radiators, heat exchangers, pipes, tanks, valves and pumps, from corrosion.

It is known to detect the presence of a specific corrosion inhibitor, such as a molybdate, by chemical analysis. This is a destructive method in that the tested sample cannot be returned to the central heating system and only works for the specified inhibitor. Furthermore, although such tests may detect the presence of the specified inhibitor, they do not indicate that the inhibitor is working effectively.

Methods have been proposed for detecting the presence of a corrosion inhibitor by measuring conductivity. Again, such tests do not reveal whether the inhibitor is working effectively.

It is an object of the present invention to provide a quick effective method of checking correct inhibitor function, which works with all inhibitors and enables the tested sample to be returned to the central heating system if desired.

### SUMMARY OF THE INVENTION

According to a first aspect of the invention there is provided a method of detecting the presence of an effective corrosion inhibitor in a central heating system liquid, comprising simultaneously immersing clean first and second electrodes formed of different metals in the system liquid, measuring the galvanic current flowing between the electrodes after a delay, and comparing the measured current with a reference.

When the electrodes are first immersed in the liquid a relatively high galvanic current, or corrosion current, will flow. The magnitude of this current is influenced by many factors. However, when an inhibitor is present in the liquid and is in an effective condition, the galvanic current will drop significantly, for example to a level below 25 μA, within from 1 to 10 minutes, for example about 5 minutes.

The delay before measuring the galvanic current may be a predetermined period of time or the measurement may be made after the galvanic current falls to a substantially steady level. By substantially steady we mean a level which does not change by more than a specified amount over a specified period of time.

Preferably, the electrodes are initially simultaneously immersed in a liquid free of corrosion inhibitor, such as mains water, and the galvanic current flowing between the electrodes is measured after a delay to provide the reference. The delay used for the reference measurement may be the same, or calculated on the same basis, as the delay used for the measurement of the system liquid. The reference measurement and the system liquid measurement are preferably carried out at the same temperature.

The materials of which the electrodes are formed are preferably related to the metals which are used in the central heating system. Since most central heating systems include components formed of steel, one of the electrodes is preferably a steel electrode or an electrode formed from an iron-based alloy. Central heating systems also include components formed of copper or aluminium and the other electrode is therefore preferably formed of copper, aluminium, a copper-based alloy or an aluminium-based alloy. The surfaces of both electrodes, should be clean when making the measurements. In the case of reuseable electrodes, ideally they are cleaned by abrasion prior to making any measurements therewith. The cleaning should take place immediately before measurements are taken. Alternatively, disposable electrodes may be used, which do not require prior cleaning. In one embodiment, the electrodes are provided with a cover formed of abrasive material, which cleans the surfaces as the electrodes are removed therefrom.

The galvanic current measurement is ideally performed at a temperature of between 10° C. and 60° C.

In a preferred method, a portion of system liquid is removed from the central heating system before the galvanic current measurement is made. After measurement, the liquid portion may be returned to the central heating system.

According to a second aspect of the invention, there is provided a portable apparatus for detecting the presence of an effective corrosion inhibitor in a central heating system liquid, the apparatus comprising a sample container and a measurement instrument which includes first and second electrodes formed of different metals, circuitry for detecting galvanic current flowing between the electrodes when immersed in a test liquid in the container, and for generating a measurement signal indicative of the measured galvanic current.

The instrument may further include a display device, such as a digital display, which receives the measurement signal and displays the measured galvanic current. Liquid crystal displays, such as bar graph displays, are particularly suitable. The circuitry may include an analogue current to voltage converter to drive the display. The display may have a range of at least from 1 to 1000 μA, such as from 1 to 2000 μA. The use of light emitting diodes for the display is also possible. In place of a display, there may be an audible indicator, or the instrument may be adapted to be connected to a separate device, such as a laptop PC, to display the desired information.

The instrument may also include a timer which can be adapted to indicate to the user the expiry of the appropriate delay.

The parts of the instrument may be contained within a leak resistant, impact resistant and chemical resistant housing, formed, for example, of a plastics material such as PVC, ABS, polycarbonate or acetal.

In a preferred embodiment, the instrument is powered by an on-board battery, such as a low current long-life battery. An indication of battery condition may be included. The on-board battery may be omitted if the instrument is adapted to be connected to a PC, or other device having its own power supply.

The instrument is ideally a zero resistance ammeter e.g. having an input resistance of 1 Ω or less.

The apparatus provides a quick effective method of checking correct inhibitor function, works with all inhibitors and enables the tested sample to be returned to the central heating system if desired. The method and apparatus can be used to confirm that a new or refurbished installation has been correctly inhibited, whether the inhibitor needs to be replaced during a service visit to a known installation, or to investigate the condition of an unknown installation.

The invention will now be further described, purely by way of example, with reference to the accompanying drawings, in which:

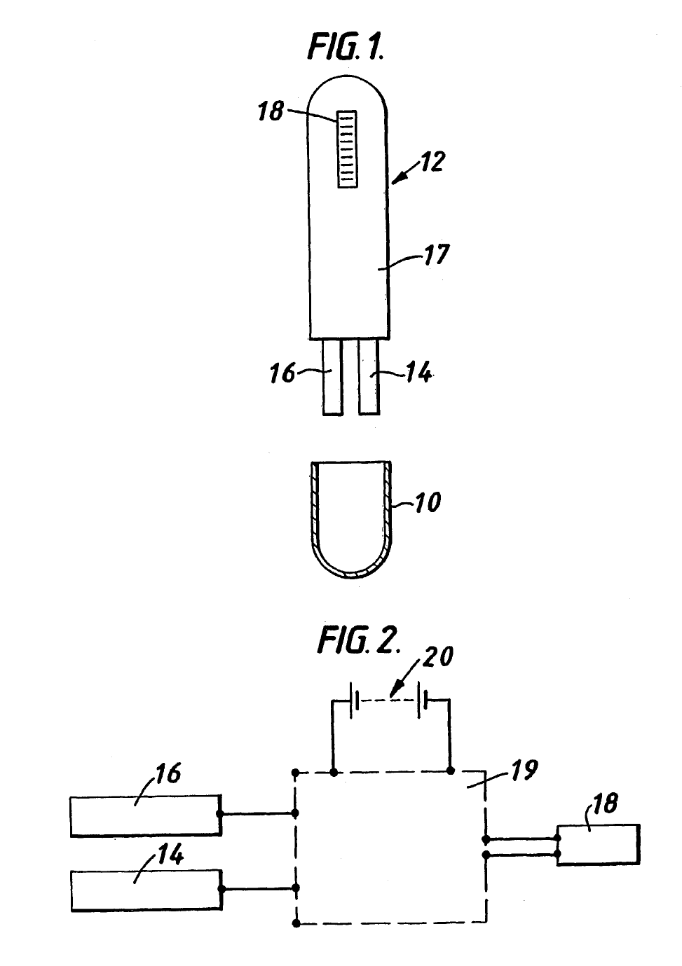

FIG. 1 shows an apparatus for use in a method according to the invention; and

FIG. 2 is a schematic representation of a circuit used in the apparatus of FIG. 1.

FIG. 1 shows a portable apparatus for detecting the presence of an effective corrosion inhibitor in a central heating system liquid.

The apparatus includes a non-metallic sample bottle 10 and a measurement instrument 12 in the form of a zero resistance ammeter which includes two cylindrical electrodes each having a length of 40 mm and a diameter of 6 mm mounted 3 mm apart on a common PVC resin housing 17, namely a mild steel electrode 14, and a copper C106 electrode 16. Also within the housing 17 there is provided circuitry 19 for detecting galvanic current flowing between the electrodes 14, 16 when immersed in a test liquid in the bottle 10, and generating a measurement signal indicative of the measured galvanic current.

The instrument 12 further includes a 10 LED bar graph digital display 18, having a range of 1 to 250 μA, which receives the measurement signal and displays the measured galvanic current.

The instrument 12 is powered by an on-board battery 20.

The apparatus is used as follows to detect the presence of an effective corrosion inhibitor in a central heating system liquid, where the system includes steel radiators and copper pipe-work.

The surfaces of the electrodes 14,16 are cleaned by rubbing with silicon carbide paper or similar abrasive prior to making any measurements therewith. The electrodes 14, 16 are rinsed, dried and then immersed together in mains water in the sample bottle 10, the mains water being known to be free of corrosion inhibitor. Only sufficient liquid is needed as will cover the electrodes. The instrument is turned on and the display is observed. Initially, the galvanic current flowing between the electrodes 14, 16 will exceed the display range (unless the electrodes are insufficiently clean), but after some minutes will fall to a steady value. This steady value is noted after about 5 minutes to provide a reference value. This will typically be between 150 and 200 μA. The instrument is turned off and the mains water in the sample bottle 10 is discarded.

A portion of system liquid of similar volume is removed from the central heating system, for example from a radiator or from a header tank of the system, and placed in the sample bottle 10. The electrodes 14, 16 are then cleaned as before and immersed together in the system liquid. The instrument is turned on and the display is observed. Initially, the galvanic current flowing between the electrodes 14, 16 may exceed the display range, but after a while will fall to a steady value. This steady value is noted after about 5 minutes to provide the measurement value to be compared with the reference value. If the system liquid contains no inhibitor, or a non-effective inhibitor, the measured value will be close to the reference value, e.g. within the range 150 to 200 μA. If the system liquid contains an effective inhibitor, the measured value will be significantly lower than the reference value, e.g. 20 μA or lower. An intermediate value will indicate a partially effective inhibitor or insufficient inhibitor.

The dimensions of the electrodes and the spacing between them are not critical. However, with electrodes of different sizes and spacing, different galvanic current levels can be expected.

1. A method of detecting the presence of an effective corrosion inhibitor in a central heating system liquid, comprising simultaneously immersing clean first and second electrodes formed of different metals in the system liquid, measuring the galvanic current flowing between the electrodes after a delay, and comparing the measured current with a reference.

2. A method according to claim 1, wherein the delay is a predetermined period of time.

3. A method according to claim 1, wherein the measurement is made after the galvanic current falls to a substantially steady level.

4. A method according to any preceding claim, wherein the electrodes are initially simultaneously immersed in a liquid free of corrosion inhibitor and the galvanic current flowing between the electrodes is measured after a delay to provide the reference.

5. A method according to any preceding claim, wherein a surface of the electrodes are cleaned by abrasion prior to making any measurements therewith.

6. A method according to any preceding claim, wherein the electrodes are formed of metals of which components of the central heating system are formed.

7. A method according to any preceding claim, wherein the electrodes are formed of steel and copper respectively.

8. A method according to any preceding claim, wherein the galvanic current measurement is performed at a temperature of between 10° C. and 60° C.

9. A method according to any preceding claim, wherein the galvanic current measurement is made using a zero resistance ammeter.

10. A method according to any preceding claim, wherein the galvanic current measurement is made on a portion of system liquid removed from the central heating system.

11. A portable apparatus for detecting the presence of an effective corrosion inhibitor in a central heating system liquid, the apparatus comprising a sample container and a measurement instrument which includes first and second electrodes formed of different metals, circuitry for detecting galvanic current flowing between the electrodes when immersed in a test liquid in the container, and for generating a measurement signal indicative of the measured galvanic current.

12. A portable apparatus according to claim 11, wherein the instrument further includes a display device which receives the measurement signal and displays the measured galvanic current.

13. A portable apparatus according to claim 12, wherein the display device is a digital display device.

14. A portable apparatus according to claim 13, wherein the display device is a bar graph display device.

15. A portable apparatus according to any one of claims 11 to 14, wherein the instrument is powered by an on-board battery.

16. A portable apparatus according to any one of claims 10 to 14, wherein the instrument is a zero resistance ammeter.

17. A method of detecting the presence of an effective corrosion inhibitor in a central heating system liquid, substantially as hereinbefore described.

18. A portable apparatus for detecting the presence of an effective corrosion inhibitor in a central heating system liquid, substantially as hereinbefore described, with reference to the accompanying drawings.
